(19) United States
(12) Patent Application Publication
(10) Pub. No.: US 2019/0153210 A1
(43) Pub. Date: May 23, 2019

(54) RESIN COMPOSITION FOR FORMING PROTECTIVE FILM AND PROTECTIVE FILM

(71) Applicant: FUJIFILM Corporation, Tokyo (JP)

(72) Inventors: Yu IWAI, Haibara-gun (JP); Mitsuru SAWANO, Haibara-gun (JP)

(73) Assignee: FUJIFILM Corporation, Tokyo (JP)

(21) Appl. No.: 16/257,543

(22) Filed: Jan. 25, 2019

Related U.S. Application Data
(63) Continuation of application No. PCT/JP2017/026785, filed on Jul. 25, 2017.

(30) Foreign Application Priority Data
Jul. 28, 2016 (JP) 2016-148740
Jan. 27, 2017 (JP) 2017-012855

(51) Int. Cl. C08L 29/14; C08K 5/3475; C08K 5/3492; C08K 5/19; H01L 21/02

(52) U.S. Cl. CPC C08L 29/14; C08K 5/3475; H01L 21/02266; C08K 5/19; C08K 5/3492

(57) ABSTRACT

Provided are a resin composition which allows laser ablation processing, allows removal of a protective film itself after the processing, and is capable of forming a protective film having peeling resistance, and a protective film. The resin composition for forming a protective film contains polyvinyl acetal, a light absorbing agent, and a solvent.

### CROSS-REFERENCE TO RELATED APPLICATIONS

This application is a Continuation of PCT International Application No. PCT/JP2017/026785 filed on Jul. 25, 2017, which claims priority under 35 U.S.C § 119(a) to Japanese Patent Application No. 2016448740 filed on Jul. 28, 2016 and Japanese Patent Application No. 2017-012855 filed on Jan. 27, 2017. Each of the above applications) is hereby expressly incorporated by reference, in its entirety, into the present application.

### BACKGROUND OF THE INVENTION

### 1. Field of the Invention

The present invention relates to a resin composition for forming a protective film and a protective film.

### 2. Description of the Related Art

In a case of manufacturing an element such as a semiconductor element, in various processing steps, a protective film may be used so as to avoid damage to each member constituting an element such as a semiconductor element.

For example, JP2007-299947A discloses a protective film used in a case of manufacturing a semiconductor element.

### SUMMARY OF THE INVENTION

As described above, the protective film is used for protecting each member constituting an element such as a semiconductor element in various processing steps in a case of manufacturing an element such as a semiconductor element.

In a case where it is desired to partially impart such a protective film, it is generally performed to remove a part of the protective film, which has been tentatively formed on the entire surface, by laser ablation processing.

In addition, as the protective film, there may be a permanent protective film which remains as a permanent film in an element such as a semiconductor element, and there may be a temporary protective film which is removed after a desired processing step is completed. It is necessary that the temporary protective film can be removed without any residues, but it is required that the temporary protective film is not peeled off during processing steps.

Under such circumstances, there is a necessity for a protective film which allows laser ablation processing, allows removal of the protective film itself after the processing, and cannot be peeled off during processing steps. However, there is no material that satisfies all of them.

An object of the present invention is to solve the above problems. Specifically, an object of the present invention is to provide a resin composition which allows laser ablation processing, allows removal of a protective film itself after the processing, and is capable of forming a protective film having peeling resistance, and a protective film.

Under these circumstances, as a result of investigations made by the present inventors, it was found that a composition for forming a protective film in which a light absorbing agent and a solvent are blended with polyvinyl acetal solves the above problems. Specifically, the above problems have been solved by the following means <1>, and preferably <2> to <18>.

<1> A resin composition for forming a protective film, comprising:

polyvinyl acetal;

a light absorbing agent; and

a solvent.

<2> The resin composition according to <1>,

in which the polyvinyl acetal includes polyvinyl butyral.

<3> The resin composition according to <1> or <2>,

in which the light absorbing agent absorbs light having any one or more wavelengths in a range of 190 to 1,200 nm.

<4> The resin composition according to any one of <1> to <3>,

in which the light absorbing agent has a 50% thermal mass reduction temperature of 300° C. or higher in a case of being heated at a rate of 10° C./min.

<5> The resin composition according to any one of <1> to <4>,

in which the light absorbing agent has a molar light absorption coefficient of 5,000 or higher at a wavelength of 355 nm.

<6> The resin composition according to <5>,

in which the light absorbing agent is at least one selected from an imidazole-based compound, a benzotriazole-based compound, a benzophenone-based compound, a benzoate-based compound, and a triazine-based compound.

<7> The resin composition according to <5>,

in which the light absorbing agent is at least one selected from a benzotriazole-based compound and a triazine-based compound.

<8> The resin composition according to any one of <1> to <4>,

in which the light absorbing agent has a molar light absorption coefficient of 5,000 or higher at a wavelength of 1,064 nm.

<9> The resin composition according to <8>,

in which the light absorbing agent is at least one selected from a cyanine-based compound, a merocyanine-based compound, a benzenethiol-based metal complex, a mercaptophenol-based metal complex, an aromatic diamine-based metal complex, a diimmonium-based compound, an aminium-based compound, a nickel complex compound, a phthalocyanine-based compound, an anthraquinone-based compound, and a naphthalocyanine-based compound.

<10> The resin composition according to <8>,

in which the light absorbing agent is at least one selected from a diimmonium-based compound and an aminium-based compound.

<11> The resin composition according to any one of <1> to <10>, which has a viscosity of 1 to 500 mPa·s at 25° C.

<12> The resin composition according to any one of <1> to <11>, further comprising: a releasing agent.

<13> The resin composition according to any one of <1> to <12>,

in which the light absorbing agent is contained in an amount of 10 parts by mass or higher with respect to 100 parts by mass of the polyvinyl acetal.

<14> The resin composition according to any one of <1> to <12>,

in which the light absorbing agent is contained in an amount of 20 parts by mass or higher with respect to 100 parts by mass of the polyvinyl acetal.

<15> The resin composition according to any one of <1> to <14>,

in which the solvent is an alcohol-based solvent.

<16> A protective film which is formed of the resin composition according to any one of <1> to <15>.

<17> The protective film according to <16>, which has a thickness of 1 to 10 μm.

<18> The protective film according to <16> or <17>, which has an optical density of 1.0 or higher at a wavelength of 355 nm or 1,064 nm.

According to the present invention, it is possible to provide a resin composition which allows laser ablation processing, allows removal of a protective film itself after the processing, and is capable of forming a protective film having peeling resistance, and a protective film.

### DESCRIPTION OF THE PREFERRED EMBODIMENTS

Hereinafter, contents of the present invention will be described in detail. In the present specification, “to” is used to include numerical values described before and after the preposition “to” as a lower limit value and an upper limit value.

Description of constituent elements in the present invention as described below may be made based on representative embodiments of the present invention. However, the present invention is not limited to such embodiments.

In the present specification, the term “step” includes not only an independent step, but also steps in a case where an intended action of the step is achieved even though it is not possible to make a clear distinction from the other step.

In the present specification, unless otherwise specified, a weight-average molecular weight (Mw) and a number-average molecular weight (Mn) are defined as polystyrene-equivalent values according to gel permeation chromatography (GPC measurement). In the present specification, the weight-average molecular weight (Mw) and the number-average molecular weight (Mn) can be obtained, for example, by using HLC-8220 (manufactured by Tosoh Corporation) and using, as a column, GUARD COLUMN HZ-L, TSKgel Super HZM-M, TSK gel Super HZ4000, TSK gel Super HZ3000, TSK gel Super HZ2000 (manufactured by Tosoh Corporation). Unless otherwise specified, tetrahydrofuran (THF) is used as an eluent. In addition, unless otherwise specified, detection is made using a detector having an ultraviolet (UV) wavelength of 254 nm.

The resin composition for forming a protective film of the embodiment of the present invention is characterized by containing polyvinyl acetal, a light absorbing agent, and a solvent. With such a constitution, it is possible to form a protective film which allows laser ablation processing, allows removal of the protective film itself after the processing, and has peeling resistance. Furthermore, use of an alcohol-based solvent as the solvent makes it possible to cause the protective film itself to be dissolved in an alcohol-based solvent and removed.

### Polyvinyl Acetal

The polyvinyl acetal used in the present invention is a compound which is obtained by cyclic acetalization of polyvinyl alcohol (obtained by saponifying polyvinyl acetate), or a derivative thereof (polyvinyl alcohol derivative). As the polyvinyl acetal derivative, the above-mentioned modified polyvinyl acetal and a polyvinyl acetal derivative composed of an acetal unit and another copolymerization unit are exemplified.

For a content of acetal in the polyvinyl acetal derivative, a vinyl alcohol unit to be acetalized is preferably 30% to 90% by mol, more preferably 40% to 85% by mol, and even more preferably 45% to 78% by mol, with respect to a total mol number of a vinyl acetate monomer which is a raw material that constitutes the polyvinyl acetal.

The vinyl alcohol unit in the polyvinyl acetal derivative is preferably 0% to 70% by mol, more preferably 5% to 50% by mol, and particularly preferably 22% to 45% by mol, with respect to a total mol number of a vinyl acetate monomer which is a raw material that constitutes the polyvinyl acetal.

In addition, the polyvinyl acetal derivative may have a vinyl acetate unit as another component. A content of the vinyl acetate unit is preferably 0% to 20% by mol and more preferably 0% to 10% by mol, with respect to a total mol number of a vinyl acetate monomer which is a raw material that constitutes the polyvinyl acetal.

A modified copolymerization unit in the polyvinyl acetal derivative is preferably 0% to 30% by mol, more preferably 1% to 20% by mol, and even more preferably 1% to 10% by mol, with respect to a total mol number of a vinyl acetate monomer which is a raw material that constitutes the polyvinyl acetal.

The polyvinyl acetal derivative may further have other copolymerization units.

Examples of the polyvinyl acetal include polyvinyl butyral, polyvinyl propylal, polyvinyl ethylal, and polyvinyl methylal, with polyvinyl butyral being preferred and polyvinyl butyral derivative being more preferred. The polyvinyl butyral is a polymer obtained by butyralizing polyvinyl acetal, and a polyvinyl butyral derivative.

Examples of the polyvinyl butyral derivative include an acid-modified polyvinyl butyral derivative obtained by modifying at least a part of hydroxyl groups of polyvinyl butyral to an acid group such as a carboxyl group, a modified polyvinyl butyral derivative obtained by modifying a part of hydroxyl groups of polyvinyl butyral to a (meth)acryloyl group, a modified polyvinyl butyral derivative obtained by modifying at least a part of hydroxyl groups of polyvinyl butyral to an amino group, and a modified polyvinyl butyral derivative obtained by introducing ethylene glycol, propylene glycol, or a multimer thereof to at least a part of hydroxyl groups of polyvinyl butyral.

A molecular weight of the polyvinyl acetal is preferably 5,000 to 800,000 and more preferably 8,000 to 500,000 in terms of weight-average molecular weight from the viewpoint of maintaining a balance between peeling resistance and laser workability.

Hereinafter, as particularly preferable examples of the polyvinyl acetal, polyvinyl butyral and derivatives thereof will be described. However, the present invention is not limited thereto.

The polyvinyl butyral used in the present invention preferably contains a constitutional unit represented by Formula (1).

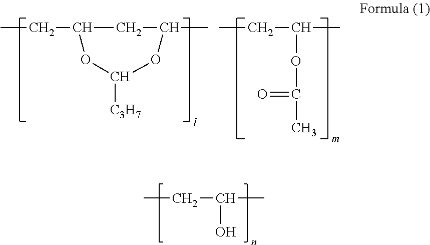

In the above formula, 1, m, and n represent contents (% by mol) of the respective constitutional units in the polyvinyl butyral of the above formula, in which 1+m+n is preferably 90 or higher, more preferably 95 or higher, and even more preferably 100.

1 is a number greater than 0 and equal to or less than 100, preferably 30 to 90, more preferably 40 to 85, and even more preferably 45 to 78.

m is a number equal to or greater than 0 and less than 100, preferably 0 to 20, more preferably 0 to 10, and even more preferably 1 to 5.

n is a number equal to or greater than 0 and less than 100, preferably 0 to 70, more preferably 5 to 50, and even more preferably 22 to 45.

The polyvinyl butyral and the derivatives thereof are also available as commercial products. As preferable specific examples thereof, from the viewpoint of solubility in alcohol (particularly ethanol and 2-propanol), “S-LECK B” series, “S-LECK K (KS)” series, manufactured by Sekisui Chemical Co., Ltd., “DENKA BUTYRAL” (manufactured by Denka Company Limited), and “Mowital” manufactured by Kuraray Co., Ltd. are preferable.

Among these, particularly preferable commercial products are shown below together with values of 1, m, and n in Formula (1) and a weight-average molecular weight.

In the “S-LECK B” series, manufactured by Sekisui Chemical Co., Ltd., “BL-1” (1=61, m=3, n=36, weight-average molecular weight of 19,000), “BL-1H” (1=67, m=3, n=30, weight-average molecular weight of 20,000), “BL-2” (1=61, m=3, n=36, weight-average molecular weight of about 27,000), “BL-5” (1=75, m=4, n=21, weight-average molecular weight of 32,000), “BL-7” (1=66, m=3, n=31, weight-average molecular weight of 40,000), “BL-S” (1=74, m=4, n=22, weight-average molecular weight of 23,000), “BM-S” (1=73, m=5, n=22, weight-average molecular weight of 53,000), and “BH-S” (1=73, m=5, n=22, weight-average molecular weight of 66,000) are mentioned.

In addition, in the “DENKA BUTYRAL” series, manufactured by Denka Company Limited, “#3000-1” (1=71, m=1, n=28, weight-average molecular weight of 74,000), “#3000-2” (1=71, m=1, n=28, weight-average molecular weight of 90,000), “#3000-4” (1=71, m=1, n=28, weight-average molecular weight of 117,000), “#4000-2” (1=71, m=1, n=28, weight-average molecular weight of 152,000), “#6000-C” (1=64, m=1, n=35, weight-average molecular weight of 308,000), “#6000-EP” (1=56, m=15, n=29, weight-average molecular weight of 381,000), “#6000-CS” (1=74, m=1, n=25, weight-average molecular weight of 322,000), and “#6000-AS” (1=73, m=1, n=26, weight-average molecular weight of 242,000) are mentioned.

Furthermore, in the “Mowital” series manufactured by Kuraray Co., Ltd., “B30T” (1=63, m 32 2, n=35, weight-average molecular weight of 33,000), “B6OH” (1=70, m=2, n=28, weight-average molecular weight of 55,000), and “B3OHH” (1=79, m=2, n=19, weight-average molecular weight of 33,000) are mentioned.

In the resin composition of the embodiment of the present invention, a lower limit value for an amount of the polyvinyl acetal is preferably 40% by mass or higher, more preferably 45% by mass or higher, and even more preferably 48% by mass or higher, with respect to all components excluding the solvent. An upper limit value for the amount of the polyvinyl acetal is preferably 98% by mass or lower and more preferably 96% by mass or lower, and may be 90% by mass or lower, 80% by mass or lower, 70% by mass or lower, or 60% by mass or lower.

The resin composition of the embodiment of the present invention may contain only one type of the polyvinyl acetal or may contain two or more types of the polyvinyl acetal. In a case where two or more types thereof are contained, a total amount is preferably within the above range.

### Light Absorbing Agent

The resin composition of the embodiment of the present invention contains a light absorbing agent. Use of the light absorbing agent makes it possible to perform laser ablation processing.

The light absorbing agent used in the present invention preferably absorbs light having any one or more wavelengths in a range of 190 to 1,200 nm, and more preferably absorbs light having any one or more wavelengths in ranges of 300 to 400 nm or 1,000 to 1,100 nm.

Here, absorbing light means that a molar light absorption coefficient at the wavelength is 1,000 or higher. In the present invention, at any one or more wavelengths in the above ranges, the molar light absorption coefficient is preferably 2,000 or higher, more preferably 5,000 or higher, even more preferably 8,000 or higher, and still more preferably 10,000 or higher. An upper limit value for the molar light absorption coefficient is not particularly determined, and may be, for example, 500,000 or lower and more preferably 50,000 or lower.

The molar light absorption coefficient in the present invention is measured according to the method described in Examples as described later.

For the light absorbing agent used in the present invention, a 50% thermal mass reduction temperature in a case of being heated at a rate of 10° C./min is preferably 180° C. or higher, more preferably 250° C. or higher, and even more preferably 300° C. or higher. With such a constitution, even in a case where a protective film is subjected to a high-temperature treatment, the light absorbing agent is hardly damaged, and laser ablation processing can be appropriately performed.

An upper limit of the 50% thermal mass reduction temperature in a case of being heated at a rate of 10° C./min is not particularly determined. Even a temperature, for example, 500° C. or lower, furthermore 450° C. or lower, and, in particular, 430° C. or lower is a sufficiently practical level.

In the present invention, it is preferable that the light absorbing agent has a molar light absorption coefficient of 5,000 or higher at a wavelength of 355 nm. By setting the molar light absorption coefficient to be within the above range, there is a tendency that workability in a case where laser ablation processing is used is further improved. The molar light absorption coefficient at a wavelength of 355 nm is preferably 8,000 or higher, more preferably 10,000 or higher, and even more preferably 12,000 or higher. An upper limit value for the molar light absorption coefficient at a wavelength of 355 nm is not particularly determined. Even a molar light absorption coefficient of 50,000 or lower, and furthermore 45,000 or lower is a sufficiently practical level.

The light absorbing agent having a molar light absorption coefficient of 5,000 or higher at a wavelength of 355 nm is preferably at least one selected from an imidazole-based compound, a benzotriazole-based compound, a benzophenone-based compound, a benzoate-based compound, and a triazine-based compound, with at least one selected from a benzotriazole-based compound and a triazine-based compound being more preferred.

As the light absorbing agent having a molar light absorption coefficient of 5,000 or higher at a wavelength of 355 nm, light absorbing agents commercially available as ultraviolet absorbing agents are exemplified.

Specific examples thereof can include a benzotriazole-based compound such as SUMISORB 200, SUMISORB 250, SUMISORB 300, SUMISORB 340, SUMISORB 350 (manufactured by Sumitomo Chemical Co., Ltd.), JF77, JF78, JF79, JF80, JF83 (manufactured by Johoku Chemical Co., Ltd.), TINUVIN P, TINUVIN PS, TINUVIN 99-2, TINUVIN 109, TINUVIN 329, TINUVIN 384-2, TINUVIN 900, TINUVIN 928, TINUVIN 1130 (manufactured by BASF), EVERSORB 70, EVERSORB 71, EVERSORB 72, EVERSORB 73, EVERSORB 74, EVERSORB 75, EVERSORB 76, EVERSORB 234, EVERSORB 77, EVERSORB 78, EVERSORB 80, EVERSORB 81 (manufactured by Everlight Chemical Industrial Corp.), TOMISORB 100, TOMISORB 600 (manufactured by API Corporation), SEESORB 701, SEESORB 702, SEESORB 703, SEESORB 704, SEESORB 706, SEESORB 707, SEESORB 709 (manufactured by Shipro Kasei Kaisha, Ltd.);

a benzophenone-based compound such as SUMISORB 130 (manufactured by Sumitomo Chemical Co., Ltd.), EVERSORB 10, EVERSORB 11, EVERSORB 12 (manufactured by Everlight Chemical Industrial Corp.), TOMISORB 800 (manufactured by API Corporation), SEESORB 100, SEESORB 101, SEESORB 1015, SEESORB 102, SEESORB 103, SEESORB 105, SEESORB 106, SEESORB 107, SEESORB 151 (manufactured by Shipro Kasei Kaisha, Ltd.); and

a benzoate-based compound such as SUMISORB 400 (manufactured by Sumitomo Chemical Co., Ltd.) and phenyl salicylate; and a triazine-based compound such as TINUVIN 400, TINUVIN 405, TINUVIN 460, TINUVIN 477, TINUVIN 477DW, TINUVIN 479 (manufactured by BASF).

Furthermore, examples thereof include, in addition to the above, diene-based compounds described in paragraphs 0022 to 0037 of JP2009-265642A (paragraphs 0040 to 0061 of corresponding US2011/0039195A), contents of which are incorporated herein.

Examples of commercial products include a diethylamino-phenylsulfonyl-pentadienoate-based ultraviolet absorbing agent (trade name: DPO, manufactured by Fujifilm Fine Chemicals Co., Ltd.).

In the present invention, for the light absorbing agent, it is also preferable that a molar light absorption coefficient at a wavelength of 1,064 nm is 5,000 or higher. By setting the molar light absorption coefficient to be within the above range, there is a tendency that workability in a case where laser ablation processing is performed is further improved. The molar light absorption coefficient at a wavelength of 1,064 nm is preferably 8,000 or higher, more preferably 11,000 or higher, and even more preferably 14,000 or higher. An upper limit value for the molar light absorption coefficient at a wavelength of 1,064 nm is not particularly determined. Even a molar light absorption coefficient of 24,000 or lower, and furthermore 19,000 or lower is a sufficiently practical level.

The light absorbing agent having a molar light absorption coefficient of 5,000 or higher at a wavelength of 1,064 nm is preferably at least one selected from a cyanine-based compound, a merocyanine-based compound, a benzenethiol-based metal complex, a mercaptophenol-based metal complex, an aromatic diamine-based metal complex, a diimmonium-based compound, an aminium-based compound, a nickel complex compound, a phthalocyanine-based compound, an anthraquinone-based compound, and a naphthalocyanine-based compound, more preferably at least one selected from a diimmonium-based compound and an aminium-based compound, and even more preferably at least one selected from an aminium-based compound.

As the light absorbing agent having a molar light absorption coefficient of 5,000 or higher at a wavelength of 1,064 nm, light absorbing agents commercially available as infrared absorbing agents are exemplified.

Specifically, a cyanine-based compound (CY-2, CY-4, CY-9, manufactured by Nippon Kayaku Co., Ltd., IRF-106, IRF-107, manufactured by FUJIFILM Corporation, YKR 2900, manufactured by Yamamoto Kasei Co., Ltd.);

a diimmonium-based compound (NIR-AM1, NIR-IM1, manufactured by Nagase ChemteX Corporation, IRG-022, IRG-023, manufactured by Nippon Kayaku Co., Ltd., CIR-1080, CIR-1081, manufactured by Japan Carlit Co., Ltd.);

an aminium-based compound (CIR-960, CIR-961, CIR-963, manufactured by Japan Carlit Co., Ltd., IRG-002, IRG-003, IRG-003K, manufactured by Nippon Kayaku Co., Ltd.);

a phthalocyanine-based compound (TX-305A manufactured by Nippon Shokubai Co., Ltd.);

a nickel complex compound (SIR-130, SIR- 132, manufactured by Mitsui Chemicals Inc., MIR-101, MIR-102, MIR-1011, MIR-1021, manufactured by Midori Kagaku Co., BBDT-NI, manufactured by Sumitomo Chemical Co., Ltd.);

an anthraquinone-based compound (IR-750, manufactured by Nippon Kayaku Co., Ltd.); and

a naphthalocyanine-based compound (YKR5010, manufactured by Yamamoto Kasei Co., Ltd.) can be mentioned.

Furthermore, in addition to the above, a polymethine-based compound (IR-820B, manufactured by Nippon Kayaku Co., Ltd.), an inorganic material type (YTTERBIUM UU-HP, manufactured by Shin-Etsu Chemical Co., Ltd., INDIUM TIN OXIDE, manufactured by Sumitomo Metal Industries, Ltd.), and the like are mentioned.

In the resin composition of the embodiment of the present invention, a lower limit value for an amount of the light absorbing agent is preferably 0.1 part by mass or higher, more preferably 1 part by mass or higher, and even more preferably 4 parts by mass or higher, with respect to 100 parts by mass of a polyvinyl acetal resin. The lower limit may be 10 parts by mass or higher, 20 parts by mass or higher, 27 parts by mass or higher, 30 parts by mass or higher, or 40 parts by mass or higher. An upper limit value for the amount of the light absorbing agent is preferably 120 parts by mass or lower, more preferably 110 parts by mass or lower, and even more preferably 105 parts by mass or lower.

The resin composition of the embodiment of the present invention may contain only one type of the light absorbing agent or may contain two or more types of the light absorbing agents. In a case where two or more types thereof are contained, a total amount is preferably within the above range.

### Solvent

The resin composition of the embodiment of the present invention contains a solvent. The solvent is not particularly determined in terms of types thereof as long as the solvent dissolves a resin component of the resin composition to some extent, and can be selected from an alcohol-based solvent, a cellosolve-based solvent, a ketone-based solvent, an amide-based solvent, an ether-based solvent, and an ester-based solvent, with an alcohol-based solvent being preferred. In a case where the alcohol-based solvent is used as the solvent, it is easy to remove a protective film with a removal solvent that contains an alcohol-based solvent in a step of removing the protective film.

The solvent contained in the resin composition of the embodiment of the present invention is preferably a solvent having a boiling point lower than 100° C. from the viewpoint of forming a protective film on side surfaces of a roughness portion on a substrate.

For the resin composition of the embodiment of the present invention, preferably 80% by mass or higher of the solvent contained in the resin composition is an alcohol-based solvent, and more preferably 90% by mass or higher thereof is an alcohol-based solvent.

The alcohol-based solvent that can be used in the present invention is preferably at least one selected from alcohols, polyhydric alcohols, or polyhydric alcohol ethers, and is more preferably at least one selected from alcohols.

Specific examples of the alcohol-based solvent include the following.

As the alcohols, monovalent linear or branched aliphatic alcohols having 1 to 20 carbon atoms and monovalent aliphatic cyclic alcohols having 4 to 20 carbon atoms are mentioned. For example, methanol, ethanol, 1-propanol, 2-propanol, 1-butyl alcohol, isobutanol, secondary butanol, tertiary butanol, pentanol, hexanol, 3-methoxy-2-propanol, 3-methoxy-1-propanol, 1-octanol, cyclohexanol, benzyl alcohol, and the like are preferably mentioned.

As the polyhydric alcohols, divalent or higher linear or branched aliphatic alcohols having 2 to 20 carbon atoms and divalent or higher aliphatic cyclic alcohols having 4 to 20 carbon atoms. The number of hydroxyl groups in one molecule is preferably 2 to 6, more preferably 2 to 4, and even more preferably 2 or 3. In addition, the polyhydric alcohols preferably contain one or more alkyleneoxy groups having 2 to 6 carbon atoms in a hydrocarbon chain. For example, ethylene glycol, diethylene glycol, triethylene glycol, polyethylene glycol, propylene glycol, dipropylene glycol, polypropylene glycol, butylene glycol, hexanediol, pentanediol, glycerin, hexanetriol, thiodiglycol, 2-methylpropanediol, and the like are preferably mentioned.

As the polyhydric alcohol ethers, ethers in which a hydrogen atom of a hydroxyl group in divalent or higher linear or branched aliphatic alcohols having 3 to 20 carbon atoms is substituted with an aliphatic hydrocarbon group having 1 to 10 carbon atoms or an aromatic hydrocarbon group having 6 to 12 carbon atoms, and ethers in which a hydrogen atom of a hydroxyl group of divalent or higher aliphatic cyclic alcohols having 4 to 20 carbon atoms is substituted with an aliphatic hydrocarbon group having 1 to 10 carbon atoms or an aromatic hydrocarbon group having 6 to 12 carbon atoms are mentioned. Further, the polyhydric alcohol ethers preferably contain, as ether bonds, one or more alkyleneoxy groups having 2 to 6 carbon atoms in a hydrocarbon chain, in addition to ether bonds in which hydroxyl groups of polyhydric alcohol have been etherified. For example, ethylene glycol monomethyl ether, ethylene glycol monoethyl ether, ethylene glycol mononormal butyl ether, ethylene glycol monotertiary butyl ether, diethylene glycol monoethyl ether, diethylene glycol monomethyl ether, diethylene glycol monobutyl ether, propylene glycol monomethyl ether, 1-ethoxy-2-propanol, propylene glycol monobutyl ether, tripropylene glycol monomethyl ether, dipropylene glycol monomethyl ether, triethylene glycol monomethyl ether, triethylene glycol monoethyl ether, triethylene glycol monobutyl ether, ethylene glycol monophenyl ether, propylene glycol monophenyl ether, and the like are preferably mentioned.

As the alcohol-based solvent, monovalent linear or branched aliphatic alcohols having 1 to 20 carbon atoms are preferable, and monovalent linear or branched aliphatic alcohols having 1 to 8 carbon atoms are most preferably used.

In the resin composition of the embodiment of the present invention, a lower limit value for an amount of the solvent is preferably 50% by mass or higher, more preferably 70% by mass or higher, even more preferably 80% by mass or higher, and still more preferably 85% by mass or higher, with respect to the composition. An upper limit value for the amount of the solvent is preferably 99% by mass or lower, and more preferably 95% by mass or lower.

The resin composition of the embodiment of the present invention may contain only one type of the solvent or two or more types of the solvents. In a case where two or more types thereof are contained, a total amount is preferably within the above range.

### Releasing Agent

The resin composition of the embodiment of the present invention may contain a releasing agent. Use of the releasing agent makes it possible to remove a protective film by peeling.

The releasing agent preferably contains at least one of a fluorine atom or a silicon atom.

Examples of the releasing agent containing a fluorine atom include FLORADE FC-4430, FC-4431, manufactured by Sumitomo 3M Ltd., SURFLON S-241, S-242, S-243, manufactured by Asahi Glass Co., Ltd., F TOP EF-PN31M-03, EF-PN31M-04, EF-PN31M-05, EF-PN31M-06, MF-100, manufactured by Mitsubishi Materials Electronic Chemicals Co., Ltd., Polyfox PF-636, PF-6320, PF-656, PF-6520, manufactured by OMNOVA Solutions Inc., FTERGENT 250, 251, 222F, 212M, DFX-18, manufactured by NEOS COMPANY LIMITED, UNIDYNE DS-401, DS-403, DS-406, DS-451, DSN-403N, manufactured by DAIKIN INDUSTRIES, LTD., MEGAFACE F-430, F-444, F-477, F-553, F-556, F-557, F-559, F-562, F-565, F-567, F-569, R-40, manufactured by DIC Corporation, and Capstone FS-3100, Zonyl FSO-100, manufactured by DuPont.

The releasing agent containing a silicon atom is preferably a silicone resin. Specifically, dimethyl silicone oil, methylphenyl silicone oil, methylhydrogen silicone oil, alkyl-modified silicone oil, alkoxy-modified silicone oil, polyether silicone oil, mercapto-modified silicone oil, amino-modified silicone oil, epoxy-modified silicone oil, carboxy-modified silicone oil, acrylate-modified silicone oil, methacrylate-modified silicone oil, fluorine-modified silicone oil, hydroxy group-modified silicone oil, and the like can be mentioned.

In addition, commercial products can also be used. For example, it is possible to use commercial products such as trade names “BYK-300”, “BYK-301/302”, “BYK-306”, “BYK-307”, “BYK-310”, “BYK-315”, “BYK-313”, “BYK-320”, “BYK-322”, “BYK-323”, “BYK-325”, “BYK-330”, “BYK BYK-331”, “BYK-333”, “BYK-337”, “BYK-341”, “BYK-344”, “BYK-345/346”, “BYK-347”, “BYK-348”, “BYK-349”, “BYK-370”, “BYK-375”, “BYK-377”, “BYK-378”, “BYK-UV3500”, “BYK-UV3510”, “BYK-UV3570”, “BYK-3550”, “BYK-SILCLEAN3700”, “BYK-SILCLEAN3720” (all manufactured by BYK Chemie Japan Co., Ltd.), trade names “AC FS 180”, “AC FS 360”, “AC S 20” (all manufactured by Algin Chemie), trade names “POLYFLOW KL-400X”, “POLYFLOW KL-400HF”, “POLYFLOW KL-401”, “POLYFLOW KL-402”, “POLYFLOW KL-403”, “POLYFLOW KL-404”, “POLYFLOW KL-700” (all manufactured by Kyoeisha Chemical Co., Ltd.), trade names “KP-301”, “KP-306”, “KP-109”, “KP-310”, “KP-310B”, “KP-323”, “KP-326”, “KP-341”, “KP-104”, “KP-110”, “KP-112”, “KP-360A”, “KP-361”, “KP-354”, “KP-355”, “KP-356”, “KP-357”, “KP-358”, “KP-359”, “KP-362”, “KP-365”, “KP-366”, “KP-368”, “KP-369”, “KP-330”, “KP-650”, “KP-651”, “KP-390”, “KP-391”, “KP-392”, “KF-105”, “KF-6017”, “X-22-163A”, “X-22-169AS”, “X-22-160AS”, “X-22-164A”, “X-22-3710”, “X-22-167B”, “X-22-4272” (all manufactured by Shin-Etsu Chemical Co., Ltd.), trade names “LP-7001”, “LP-7002”, “SH28PA”, “8032 ADDITIVE”, “57 ADDITIVE”, “L-7604”, “FZ-2110”, “FZ-2105”, “67 ADDITIVE”, “8618 ADDITIVE”, “3 ADDITIVE”, “56 ADDITIVE” (all manufactured by Dow Corning Toray Co., Ltd.), “TEGO WET 270” (manufactured by Evonik Degussa Japan Co., Ltd.), and “NBX-15” (manufactured by NEOS COMPANY LIMITED).

In the resin composition of the embodiment of the present invention, an amount of the releasing agent is preferably 0.001% to 1% by mass, more preferably 0.001% to 0.1% by mass, and even more preferably 0.001% to 0.08% by mass, with respect to all components excluding the solvent.

The resin composition of the embodiment of the present invention may contain only one type of the releasing agent or may two or more types of the releasing agents. In a case where two or more types thereof are contained, a total amount is preferably within the above range.

### Other Components

The resin composition of the embodiment of the present invention may contain other components within a scope that does not depart from the gist of the present invention. Specifically, other polymer compounds, antioxidants, surfactants, intimate-attachment promoters, and fillers are exemplified.

A viscosity at 25° C. of the resin composition of the embodiment of the present invention is preferably 1 to 500 mPa·s, more preferably 5 to 100 mPa·s, and even more preferably 10 to 30 mPa·s. By setting the viscosity to be within such a range, it is possible to form a conformal protective film that satisfactorily follows roughness of an element at the time of forming a film (for example, at the time of spray-coating).

As a storage container for the composition of the present invention, a storage container known in the related art can be used. In addition, as the storage container, for the purpose of suppressing incorporation of impurities into a raw material or composition, it is also preferable to use a multilayer bottle having a container inner wall composed of six types of six layers of resin, or a bottle having a seven-layer structure of 6 types of resin. Examples of such a container include the container described in JP2015-123351A, contents of which are incorporated herein.

The resin composition of the embodiment of the present invention is used for forming a protective film. The protective film of the embodiment of the present invention is used for protecting various members constituting a semiconductor element, an image sensor, or the like, or the whole element.

A thickness of the protective film can be appropriately determined depending on an application or the like. The thickness is preferably 1 to 10 μm, and more preferably 2 to 8 μm.

In the protective film of the embodiment of the present invention, an optical density at a wavelength of 355 nm or 1,064 nm is preferably 0.2 or higher, more preferably 0.3 or higher, even more preferably 0.6 or higher, and still more preferably 1.0 or higher. An upper limit for the optical density at a wavelength of 355 nm or 1,064 nm is not particularly determined. The upper limit is preferably 20 or lower, more preferably 10 or lower, and even more preferably 8 or lower. By setting the optical density to be within such a range, laser ablation workability can be exerted more effectively.

The optical density in the present invention is measured by the method described in Examples as described later.

The resin composition of the embodiment of the present invention is preferably used for manufacturing an element such as a semiconductor. Specifically, use thereof includes forming a protective film on a member using the resin composition of the embodiment of the present invention, performing laser ablation processing, and then removing the remaining protective film by using a solvent.

### Protective Film Forming Step

In a protective film forming step, a protective film is formed on a member using the resin composition of the embodiment of the present invention.

As a method for forming the protective film of the embodiment of the present invention on the member, a commonly known coating method such as spin coating, slit coating, spray coating, and ink jet coating can be used. In a case of using a substrate having roughness such as a substrate with bumps or a substrate with steps, in order to form a protective film even on side surfaces of the roughness, it is desirable to use spray coating, ink jet coating, or slit coating.

It is also preferable to include a heating step (for drying the solvent) after a film formation and before a laser ablation processing step.

A heating temperature is preferably 60° C. to 200° C., and more preferably 80° C. to 120° C.

A heating time is preferably 10 to 600 seconds, more preferably 30 to 300 seconds, and even more preferably 40 to 90 seconds.

Heating can be carried out by means provided in a usual exposure/development machine, and may be carried out using a hot plate or the like.

### Laser Ablation Processing Step

In a laser ablation processing step, laser ablation processing is carried out with respect to the protective film. In the laser ablation processing, it is preferable that a part of the protective film is removed, and necessary processing is performed on a site where the protective film has been removed. Here, the laser ablation processing is a processing method of selectively irradiating a material to be processed, which contains a component to be evaporated or decomposed by laser light irradiation, with laser light thereby selectively removing exposed regions.

There is no limitation on a light source wavelength used in a laser ablation apparatus in the present invention, and infrared light, visible light, ultraviolet light, far ultraviolet light, extreme ultraviolet light, X ray, electron beam, and the like can be exemplified. Light having a wavelength of 200 to 1300 nm is preferable, light having a wavelength of 300 to 1,200 nm is more preferable, and light having a wavelength of 300 to 400 nm or 900 to 1,200 nm is particularly preferable. Specifically, a YAG laser (1,064 nm), a YAG-THG laser (355 nm), and an excimer laser (308 nm, 351 nm) are preferable. In addition, a pulse width of the laser is preferably as short as possible. The pulse width is preferably 100 nanoseconds (nsec) or shorter, more preferably 10 nsec or shorter, and even more preferably 3 nsec or shorter.

### Removing Step

In a removing step, the remaining protective film is removed using a solvent. As the solvent, an alcohol-based solvent and an ester-based solvent are preferable, with an ester-based solvent being more preferred. From the viewpoint of preventing a foreign matter re-adhering on a metal film or the like after removal, a solvent having a boiling point of 100° C. or higher is more preferable, and a solvent having a boiling point of 130° C. or higher is even more preferable. As a removal method, for example, a method (dipping method) of immersing a member in a tank filled with a solvent for a predetermined time, a method (shaking method) of shaking the entire container which is dipped, a method (puddle method) in which a solvent is raised by surface tension to a surface of a member and removed by being allowed to stand for a certain period of time, a method (spraying method) of spraying a solvent on a surface of a member, a method (showering method) of jetting a high-pressure solvent on a surface of a member, a method (dynamic dispense method) of continuously ejecting a solvent on a member which is rotating at a constant speed while scanning a solvent ejection nozzle at a constant speed, or the like can be applied.

For the alcohol-based solvent, preferable examples thereof include the alcohol-based solvents mentioned in the section for the solvent contained in the resin composition as described above. As the alcohol-based solvent, an alcohol-based solvent having a boiling point higher than 100° C. is preferable, and an alcohol-based solvent having a boiling point higher than 130° C. is more preferable. More specifically, an alcohol-based solvent (isobutyl alcohol, 1-butanol, or the like) having a boiling point higher than 100° C. are more preferable, and an alcohol-based solvent (cyclohexanol or the like) having a boiling point higher than 130° C. is even more preferable. An upper limit for the boiling point of the alcohol-based solvent is not particularly determined, and can be, for example, 200° C. or lower. In a case where the boiling point is 200° C. or lower, a time required for drying can be shortened, and a production rate can be improved.

As the ester-based solvent, preferable examples thereof include methyl acetate, ethyl acetate, isopropyl acetate, n-butyl acetate, isobutyl acetate, amyl formate, isoamyl acetate, butyl propionate, isopropyl butyrate, ethyl butyrate, butyl butyrate, methyl lactate, ethyl lactate, alkyl alkyloxy acetate (such as methyl alkyloxy acetate, ethyl alkyloxy acetate, and butyl alkyloxy acetate (for example, methyl methoxy acetate, ethyl methoxy acetate, butyl methoxy acetate, methyl ethoxy acetate, and ethyl ethoxy acetate)), 3-alkyloxy propionic acid alkyl esters (such as methyl 3-alkyloxy propionate and ethyl 3-alkyloxy propionate (for example, methyl 3-methoxy propionate, ethyl 3-methoxy propionate, methyl 3-ethoxy propionate, and ethyl 3-ethoxy propionate)), 2-alkyloxy propionic acid alkyl esters (such as methyl 2-alkyloxy propionate, ethyl 2-alkyloxy propionate, and propyl 2-alkyloxy propionate (for example, methyl 2-methoxy propionate, ethyl 2-methoxy propionate, propyl 2-methoxy propionate, methyl 2-ethoxy propionate, and ethyl 2-ethoxy propionate)), methyl 2-alkyloxy-2-methyl propionate and ethyl 2-alkyloxy-2-methyl propionate (for example, methyl 2-methoxy-2-methyl propionate and ethyl 2-ethoxy-2-methyl propionate), methyl pyruvate, ethyl pyruvate, propyl pyruvate, methyl acetoacetate, ethyl acetoacetate, methyl 2-oxobutanoate, and ethyl 2-oxobutanoate. As the ester-based solvent, an ester-based solvent having a boiling point higher than 100° C. is preferable, and an ester-based solvent having a boiling point higher than 130° C. is more preferable. More specifically, an ester-based solvent (n-butyl acetate or the like) having a boiling point higher than 100° C. is more preferable, and an ester-based solvent (propylene glycol 1-monomethyl ether 2-acetate or the like) having a boiling point higher than 130° C. is even more preferable. An upper limit for the boiling point of the ester-based solvent is not particularly determined, and can be, for example, 200° C. or lower. In a case where the boiling point is 200° C. or lower, a time required for drying can be shortened, and a production rate can be improved.

In the present invention, for the solvent used for removing a protective film, a solubility therein at 25° C. of the resin composition of the embodiment of the present invention is preferably 0.5% by mass or higher, and more preferably 1% to 50% by mass. By setting the solubility to be within such a range, the remaining protective film can be removed more effectively.

### EXAMPLES

Hereinafter, the present invention will be described more specifically with reference to examples. Materials, amounts used, proportions, details for treatment, treatment procedures, and the like shown in the following examples can be appropriately changed within a scope that does not depart from the gist of the present invention. Accordingly, the scope of the present invention is not limited to the following specific examples.

### (1) Preparation of Resin Composition

The respective resins, light absorbing agents, solvents, and releasing agents described in Table 1 or 2 were mixed at the respective mass proportions shown in Table 1 or 2 to prepare resin compositions.

A thermal mass reduction temperature and a molar light absorption coefficient of the light absorbing agent were measured as follows.

### Measurement of Thermal Mass Reduction Temperature

Using a calorimeter (TGA), heating was carried out at a rate of 10° C./min and a temperature at which reduction of 50% by mass occurs (50% thermal mass reduction temperature) was measured.

### Measurement of Molar Light Absorption Coefficient

Each light absorbing agent was dissolved in tetrahydrofuran (THF), absorption spectra at wavelengths of 355 nm and 1,064 nm were measured, and a molar light absorption coefficient was calculated.

The results are shown in Table 1 or Table 2. For the light absorbing agents b-1 to b-3, and b-10, the molar light absorption coefficients at 355 nm were less than 1,000. In addition, molar light absorption coefficients at 1,064 nm for light absorbing agents b-4 to b-9 were less than 1,000.

### Measurement of Viscosity at 25° C. of Resin Composition

Each of the resin compositions was measured at 25° C. using an E-type viscometer. As a result, all the resin compositions used in the examples had a viscosity within a range of 1 to 500 mPa·s.

### (2) Production of Protective Film

(2-1) Each resin composition was spin-coated on a substrate in which a plurality of 200 μm-diameter solder bumps were formed on a disk-shaped silicon wafer having a diameter of 4 inches (1 inch is 2.54 cm), and heating was performed on a hot plate at 100° C. for 2 minutes so that a protective film with a thickness of 5 μm was produced on a flat part having no solder bumps and a protective film-laminated body was obtained.

(2-2) As another production method, slit coating was performed on the same substrate as above and heating was performed on a hot plate at 100° C. for 2 minutes so that a protective film-laminated body was similarly obtained.

### (3) Evaluation

(a) Coatability

A thickness of the protective film that adheres on a side surface of the solder bump of the above protective film-laminated body was cross-sectionally cut using a focused ion beam processing (FIB) apparatus, measurement was performed at five locations, and an average film thickness thereof was taken as a film thickness of the side surface of the bump. It is most desirable from the viewpoint of uniformity of dissolution removal of the protective film that the side surface of the bump has the same thickness as the flat part, and it is sufficient that the side surface of the bump has the film which is adhered to be 1% or higher of the film thickness of the flat part.

A: A film thickness of the side surface of the bump was 50% or higher as compared with a film thickness of the flat part.

B: A film thickness of the side surface of the bump was less than 50% and equal to or greater than 1% as compared with a film thickness of the flat part.

C: There was a portion having a film thickness of less than 1% on the side surface of the bump.

(b) Peeling Resistance

The protective film-laminated body was immersed in water at 25° C. for 1 hour, and changes in the protective film were observed. In a case where there are no changes such as dissolution and swelling, it can be presumed that good peeling resistance is exhibited during a process using water. Evaluation was performed according to the following criteria. A which indicates that no changes are observed is the most preferable result.

A: No changes were observed.

B: Changes such as swelling were observed. However, complete dissolution did not occur and this allowed use without any problems in practical use.

C: Complete dissolution occurred, and this did not allow use as a protective film.

(c) Laser workability (removal suitability in laser ablation processing)

A line with a width of 100 μm and a length of 5 mm was produced on the protective film of the protective film-laminated body using laser light having a wavelength described in Table 1 or 2, by causing a laser beam of 60 μm square to be focused thereon, performing 5 mm scanning at a pulse width of 5 ns, a repetition frequency of 50 Hz, and a scanning speed of 1.5 mm/s, and then performing scanning once more with a shift by 50 μm orthogonal to the scanning direction, and processing suitability of the protective film for laser ablation processing was identified. A shape of the line was observed with an optical microscope and evaluation was performed according to the following criteria. A is most preferred.

A: There were no residues of the protective film on a line, and a clean line could be produced.

B: There was slight roughness on a side wall of a line. However, there were no residues of the protective film on the line, and this allows use without any problems.

C: There were some residues of the protective film on a line. However, this allowed use without any problems in practical use.

D: Residues of the protective film remained and this did not allow use.

(d) Formation of metal film on protective film

Copper of 100 nm was formed, with a sputtering method, on the protective film-laminated body after the laser processing, to obtain a protective film-laminated body with a metal film.

(e) Removability of Protective Film

Using the above-mentioned protective film-laminated body with a metal film, removability of the protective film was identified in the dissolution removal described in Table 1 or 2 (described as either “dissolution 1” or “dissolution 2” in the tables), or the peeling removal method (described as “peeling” in the tables).

(f-1) Dissolution Removal 1 (Dissolution 1)

The protective film-laminated body with a metal film was immersed in 2-propanol at 25° C. for 2 minutes and then taken out therefrom. Washing was further performed with 10 mL of 2-propanol, and removability of the protective film was visually identified. Evaluation was performed according to the following criteria.

A: Removal could be done without residues.

B: Residues remained.

In addition, re-adhesion of the metal film in a removal solution after removal of the protective film becomes a problem. Thus, re-adhesion of the metal film was identified with an optical microscope.

A: There was no re-adhesion.

B: Re-adhesion occurred at less than 10 locations.

C: Re-adhesion occurred at equal to or greater than 10 locations.

(f-2) Dissolution Removal 2 (Dissolution 2)

The protective film-laminated body with a metal film was immersed in propylene glycol 1-monomethyl ether 2-acetate at 25° C., a lid was closed to perform sealing, shaking was performed at 60 Hz, and the substrate of which the protective film was removed was taken out, and dried in the atmosphere. Removability of the protective film and re-adhesion of the metal film were evaluated according to the same criteria as above.

(f-3) Peeling Removability (Peeling)

Scotch tape was attached to 2 cm of an end portion of the protective film in the protective film-laminated body with a metal film. The attached Scotch tape was pulled in a direction perpendicular to a silicon wafer surface and removability by peeling was visually identified. Evaluation was performed according to the following criteria. In addition, re-adhesion of the metal film was evaluated according to the same criteria as above.

A: Removal could be done without residues.

B: Residues remained.

(g) Optical Density of Protective Film

Each resin composition was spin-coated on a disk-shaped glass having a diameter of 4 inches (1 inch is 2.54 cm), and heated on a hot plate at 100° C. for 2 minutes to produce a protective film having a thickness of 5μm. A transmission spectrum of the protective film coated on the glass was measured, and OD values (optical densities) in transmittance at 355 nm and 1,064 nm were calculated.

TABLE 1

| | | | Light absorbing agent | | | | | | | | | | |
|---|---|---|---|---|---|---|---|---|---|---|---|---|---|
| | | | | | Molar light absorption | | | | | | | Evaluation of | |
| | | | | | coefficient | | | | | | | protective film | |
| | | | | 50% | | Molar | | | | | | Coatability | |
| | | | | mass | | light | | | | Releasing | | | Side |
| | Resin | | | reduction | | absorption | | Solvent | | agent | | Coating | surface |
| | Type | Mass | Type | temperature | Wavelength | coefficient | Mass | Type | Mass | Type | Mass | Method | coatability |
| Example 1 | a-1 | 9.6 | b-1 | 410° C. | 1,064 | 16,000 | 0.4 | c-1 | 90 | — | — | Spin | B |
| Example 2 | a-2 | 9.6 | b-1 | 410° C. | 1,064 | 16,000 | 0.4 | c-1 | 90 | — | — | Spin | B |
| Example 3 | a-3 | 9.6 | b-1 | 410° C. | 1,064 | 16,000 | 0.4 | c-1 | 90 | — | — | Spin | B |
| Example 4 | a-4 | 9.6 | b-1 | 410° C. | 1,064 | 16,000 | 0.4 | c-1 | 90 | — | — | Spin | B |
| Example 5 | a-1 | 9.6 | b-2 | 400° C. | 1,064 | 16,000 | 0.4 | c-1 | 90 | — | — | Spin | B |
| Example 6 | a-1 | 9.6 | b-3 | 410° C. | 1,064 | 16,000 | 0.4 | c-1 | 90 | — | — | Spin | B |
| Example 7 | a-1 | 9.6 | b-4 | 370° C. | 355 | 18,000 | 0.4 | c-1 | 90 | — | — | Spin | B |
| Example 8 | a-1 | 9.6 | b-5 | 200° C. | 355 | 13,000 | 0.4 | c-1 | 90 | — | — | Spin | B |
| Example 9 | a-1 | 9.6 | b-6 | 220° C. | 355 | 13,000 | 0.4 | c-1 | 90 | — | — | Spin | B |
| Example 10 | a-1 | 9.6 | b-7 | 270° C. | 355 | 13,000 | 0.4 | c-1 | 90 | — | — | Spin | B |
| Example 11 | a-1 | 9.6 | b-8 | 380° C. | 355 | 12,500 | 0.4 | c-1 | 90 | — | — | Spin | B |
| Example 12 | a-1 | 9.6 | b-9 | 390° C. | 355 | 42,000 | 0.4 | c-1 | 90 | — | — | Spin | B |
| Example 13 | a-1 | 9.6 | b-1 | 410° C. | 1,064 | 16,000 | 0.4 | c-2 | 90 | — | — | Spin | B |
| Example 14 | a-1 | 9 | b-4 | 370° C. | 355 | 18,000 | 1 | c-1 | 90 | — | — | Spin | B |
| Example 15 | a-1 | 8 | b-4 | 370° C. | 355 | 18,000 | 2 | c-1 | 90 | — | — | Spin | B |
| Example 16 | a-1 | 7 | b-4 | 370° C. | 355 | 18,000 | 3 | c-1 | 90 | — | — | Spin | B |
| Example 17 | a-1 | 5 | b-4 | 370° C. | 355 | 18,000 | 5 | c-1 | 90 | — | — | Spin | B |
| Example 18 | a-1 | 9 | b-8 | 380° C. | 355 | 12,500 | 1 | c-1 | 90 | — | — | Spin | B |
| Example 19 | a-1 | 8 | b-8 | 380° C. | 355 | 12,500 | 2 | c-1 | 90 | — | — | Spin | B |
| Example 20 | a-1 | 7 | b-8 | 380° C. | 355 | 12,500 | 3 | c-1 | 90 | — | — | Spin | B |
| Example 21 | a-1 | 5 | b-8 | 380° C. | 355 | 12,500 | 5 | c-1 | 90 | — | — | Spin | B |

| | Evaluation of protective film | | | | | | | |
|---|---|---|---|---|---|---|---|---|
| | | | | Laser workability | | Removabiltiy | | |
| | Optical density | | Peeling | Laser | | | | Re-adhesion |
| | Wavelength | OD value | resistance | wavelength | Workability | Method | Removability | property |
| Example 1 | 1,064 | 0.3 | A | 1,064 | B | Dissolution 1 | A | B |
| Example 2 | 1,064 | 0.3 | A | 1,064 | B | Dissolution 1 | A | B |
| Example 3 | 1,064 | 0.3 | A | 1,064 | B | Dissolution 1 | A | B |
| Example 4 | 1,064 | 0.3 | A | 1,064 | B | Dissolution 1 | A | B |
| Example 5 | 1,064 | 0.3 | A | 1,064 | B | Dissolution 1 | A | B |
| Example 6 | 1,064 | 0.3 | A | 1,064 | B | Dissolution 1 | A | B |
| Example 7 | 355 | 0.3 | A | 355 | B | Dissolution 1 | A | B |
| Example 8 | 355 | 1.1 | A | 355 | C | Dissolution 1 | A | B |
| Example 9 | 355 | 1.0 | A | 355 | C | Dissolution 1 | A | B |
| Example 10 | 355 | 1.0 | A | 355 | C | Dissolution 1 | A | B |
| Example 11 | 355 | 0.5 | A | 355 | B | Dissolution 1 | A | B |
| Example 12 | 355 | 1.0 | A | 355 | B | Dissolution 1 | A | B |
| Example 13 | 1,064 | 1.0 | A | 1,064 | B | Dissolution 1 | A | B |
| Example 14 | 355 | 1.1 | A | 355 | B | Dissolution 1 | A | B |
| Example 15 | 355 | 1.4 | A | 355 | A | Dissolution 1 | A | B |
| Example 16 | 355 | 2.7 | A | 355 | A | Dissolution 1 | A | B |
| Example 17 | 355 | 4.8 | B | 355 | A | Dissolution 1 | A | B |
| Example 18 | 355 | 1 | A | 355 | B | Dissolution 1 | A | B |
| Example 19 | 355 | 2 | A | 355 | A | Dissolution 1 | A | B |
| Example 20 | 355 | 3 | A | 355 | A | Dissolution 1 | A | B |
| Example 21 | 355 | 5.0 | A | 355 | A | Dissolution 1 | A | B |

TABLE 2

| | | | Light absorbing agent | | | | | | | | | Evaluation of | |
|---|---|---|---|---|---|---|---|---|---|---|---|---|---|
| | | | | | Molar light absorption | | | | | | | protective film | |
| | | | | | coefficient | | | | | | | Coatability | |
| | | | | 50% | | Molar light | | | | Releasing | | | Side |
| | Resin | | | mass reduction | | absorption | | Solvent | | agent | | Coating | surface |
| | Type | Mass | Type | temperature | Wavelength | coefficient | Mass | Type | Mass | Type | Mass | Method | coatability |
| Example 22 | a-1 | 9 | b-9 | 390° C. | 355 | 42,000 | 1 | c-1 | 90 | — | — | Spin | B |
| Example 23 | a-1 | 8 | b-9 | 390° C. | 355 | 42,000 | 2 | c-1 | 90 | — | — | Spin | B |
| Example 24 | a-1 | 7 | b-9 | 390° C. | 355 | 42,000 | 3 | c-1 | 90 | — | — | Spin | B |
| Example 25 | a-1 | 5 | b-9 | 390° C. | 355 | 42,000 | 5 | c-1 | 90 | — | — | Spin | B |
| Example 26 | a-1 | 9.6 | b-1 | 410° C. | 1,064 | 16,000 | 0.4 | c-1 | 90 | d-1 | 0.004 | Spin | B |
| Example 27 | a-1 | 9.6 | b-1 | 410° C. | 1,064 | 16,000 | 0.4 | c-1 | 90 | d-2 | 0.004 | Spin | B |
| Example 28 | a-1 | 9.97 | b-10 | 410° C. | 1,064 | 72,000 | 0.03 | c-2 | 90 | — | — | Spin | C |
| Example 29 | a-1 | 7 | b-4 | 370° C. | 355 | 18,000 | 3 | c-3 | 90 | — | — | Spin | B |
| Example 30 | a-1 | 7 | b-4 | 370° C. | 355 | 18,000 | 3 | c-4 | 90 | — | — | Spin | C |
| Example 31 | a-1 | 7 | b-4 | 370° C. | 355 | 18,000 | 3 | c-5 | 90 | — | — | Spin | B |
| Example 32 | a-1 | 7 | b-4 | 370° C. | 355 | 18,000 | 3 | c-6 | 90 | — | — | Spin | C |
| Example 33 | a-1 | 7 | b-4 | 370° C. | 355 | 18,000 | 3 | c-7 | 90 | — | — | Spin | B |
| Example 34 | a-1 | 7 | b-4 | 370° C. | 355 | 18,000 | 3 | c-8 | 90 | — | — | Spin | C |
| Example 35 | a-4 | 5 | b-8 | 380° C. | 355 | 12,500 | 5 | c-1 | 90 | — | — | Spin | B |
| Example 36 | a-4 | 5 | b-8 | 380° C. | 355 | 12,500 | 5 | c-1 | 90 | — | — | Slit | A |
| Example 37 | a-4 | 5 | b-8 | 380° C. | 355 | 12,500 | 5 | c-1 | 90 | — | — | Slit | A |
| Comparative | a-1 | 10 | — | — | — | — | — | c-1 | 90 | — | — | Spin | B |
| Example 1 | | | | | | | | | | | | | |
| Comparative | a-1 | 10 | — | — | — | — | — | c-1 | 90 | — | — | Spin | B |
| Example 2 | | | | | | | | | | | | | |
| Comparative | a-5 | 10 | b-4 | 370° C. | 355 | 18,000 | — | c-1 | 90 | — | — | Spin | B |
| Example 3 | | | | | | | | | | | | | |
| Comparative | a-5 | 10 | b-4 | 370° C. | 355 | 18,000 | — | c-1 | 90 | — | — | Spin | B |
| Example 4 | | | | | | | | | | | | | |

| | Evaluation of protective film | | | | | | | |
|---|---|---|---|---|---|---|---|---|
| | | | | Laser workability | | Removabiltiy | | |
| | Optical density | | Peeling | Laser | | | | Re-adhesion |
| | Wavelength | OD value | resistance | wavelength | Workability | Method | Removability | property |
| Example 22 | 355 | 1.5 | A | 355 | B | Dissolution 1 | A | B |
| Example 23 | 355 | 2.9 | A | 355 | A | Dissolution 1 | A | B |
| Example 24 | 355 | 4.2 | A | 355 | A | Dissolution 1 | A | B |
| Example 25 | 355 | 6.0 | A | 355 | A | Dissolution 1 | A | B |
| Example 26 | 1,064 | 0.3 | A | 1,064 | B | Peeling | A | A |
| Example 27 | 1,064 | 0.3 | A | 1,064 | B | Peeling | A | A |
| Example 28 | 1,064 | 0.1 | A | 1,064 | C | Dissolution 1 | A | B |
| Example 29 | 355 | 2.7 | A | 355 | A | Dissolution 1 | A | B |
| Example 30 | 355 | 2.7 | A | 355 | A | Dissolution 1 | A | B |
| Example 31 | 355 | 2.7 | A | 355 | A | Dissolution 1 | A | B |
| Example 32 | 355 | 2.7 | A | 355 | A | Dissolution 1 | A | B |
| Example 33 | 355 | 2.7 | A | 355 | A | Dissolution 1 | A | B |
| Example 34 | 355 | 2.7 | A | 355 | A | Dissolution 1 | A | B |
| Example 35 | 355 | 4.7 | A | 355 | A | Dissolution 1 | A | B |
| Example 36 | 355 | 4.7 | A | 355 | A | Dissolution 1 | A | B |
| Example 37 | 355 | 4.7 | A | 355 | A | Dissolution 2 | A | A |
| Comparative | — | — | A | 355 | D | Dissolution 1 | A | B |
| Example 1 | | | | | | | | |
| Comparative | — | — | A | 1,064 | D | Dissolution 1 | A | B |
| Example 2 | | | | | | | | |
| Comparative | — | — | C | 355 | A | Dissolution 1 | A | B |
| Example 3 | | | | | | | | |
| Comparative | — | — | C | 1,064 | A | Dissolution 1 | A | B |
| Example 4 | | | | | | | | |

The respective components in Table 1 or Table 2 are as follows.

### Resin (Polyvinyl Acetal or Resin for Comparison)

(a-1) Polyvinyl butyral, B3OT (manufactured by Kuraray Co., Ltd.)

(a-2) Polyvinyl butyral, B6OH (manufactured by Kuraray Co., Ltd.)

(a-3) Polyvinyl butyral, B30-HH (manufactured by Kuraray Co., Ltd.)

(a-4) Polyvinyl butyral, BL-7 (manufactured by Sekisui Chemical Co., Ltd.)

(a-5) Poly(N-isopropylacrylamide) (manufactured by Aldrich) (resin for comparison)

### Light Absorbing Agent

(b-1) NIR-AM1 (aminium-based compound, manufactured by Nagase ChemteX Corporation)

(b-2) CIR-960 (aminium-based compound, manufactured by Japan Carlit Co., Ltd.)

(b-3) CIR-963 (aminium-based compound, manufactured by Japan Carlit Co., Ltd.)

(b-4) TINUVIN 1130 (benzotriazole-based compound, manufactured by BASF)

(b-5) TINUVIN P (benzotriazole-based compound, manufactured by BASF)

(b-6) TINUVIN 329 (benzotriazole-based compound, manufactured by BASF)

(b-7) TINUVIN 99-2 (benzotriazole-based compound, manufactured by BASF)

(b-8) TINUVIN 400 (triazine-based compound, manufactured by BASF)

(b-9) TINUVIN 477 (triazine-based compound, manufactured by BASF)

(b-10) NIR-IM1 (diimmonium-based compound, manufactured by Nagase ChemteX Corporation)

### Solvent

(c-1) 2-Propanol

(c-2) 1-Methoxy-2-propanol

(c-3) Ethanol

(c-4) 1-Butanol

(c-5) 1-Propanol

(c-6) 1-Octanol

(c-7) Methanol

(c-8) 2-Butanol

### Releasing Agent

(d-1) KF-6017 (silicone-based compound, manufactured by Shin-Etsu Chemical Co., Ltd.)

(d-2) F-553 (fluorine-based compound, manufactured by DIC Corporation)

As is clear from the above results, it was found that the resin composition of the embodiment of the present invention exhibits excellent laser workability and excellent removability.

In contrast, in a case where no light absorbing agent is blended (Comparative Examples 1 and 2), inferior laser workability was exhibited. On the other hand, in a case where a resin other than polyvinyl acetal was used (Comparative Examples 3 and 4), inferior peeling resistance was exhibited.

What is claimed is:

1. A resin composition for forming a protective film, comprising:
polyvinyl acetal;
a light absorbing agent; and
a solvent.

2. The resin composition according to claim 1,
wherein the polyvinyl acetal includes polyvinyl butyral.

3. The resin composition according to claim 1,
wherein the light absorbing agent absorbs light having any one or more wavelengths in a range of 190 to 1,200 nm.

4. The resin composition according to claim 1,
wherein the light absorbing agent has a 50% thermal mass reduction temperature of 300° C. or higher in a case of being heated at a rate of 10° C./min.

5. The resin composition according to claim 1 ,
wherein the light absorbing agent has a molar light absorption coefficient of 5,000 or higher at a wavelength of 355 nm.

6. The resin composition according to claim 5,
wherein the light absorbing agent is at least one selected from an imidazole-based compound, a benzotriazole-based compound, a benzophenone-based compound, a benzoate-based compound, and a triazine-based compound.

7. The resin composition according to claim 5,
wherein the light absorbing agent is at least one selected from a benzotriazole-based compound and a triazine-based compound.

8. The resin composition according to claim 1,
wherein the light absorbing agent has a molar light absorption coefficient of 5,000 or higher at a wavelength of 1,064 nm.

9. The resin composition according to claim 8,
wherein the light absorbing agent is at least one selected from a cyanine-based compound, a merocyanine-based compound, a benzenethiol-based metal complex, a mercaptophenol-based metal complex, an aromatic diamine-based metal complex, a diimmonium-based compound, an aminium-based compound, a nickel complex compound, a phthalocyanine-based compound, an anthraquinone-based compound, and a naphthalocyanine-based compound.

10. The resin composition according to claim 8,
wherein the light absorbing agent is at least one selected from a diimmonium-based compound and an aminium-based compound.

11. The resin composition according to claim 1, which has a viscosity of 1 to 500 mPa·s at 25° C.

12. The resin composition according to claim 1, further comprising:
a releasing agent.

13. The resin composition according to claim 1,
wherein the light absorbing agent is contained in an amount of 10 parts by mass or higher with respect to 100 parts by mass of the polyvinyl acetal.

14. The resin composition according to claim 1,
wherein the light absorbing agent is contained in an amount of 20 parts by mass or higher with respect to 100 parts by mass of the polyvinyl acetal.

15. The resin composition according to claim 1,
wherein the solvent is an alcohol-based solvent.

16. A protective film which is formed of the resin composition according to claim 1.

17. The protective film according to claim 16, which has a thickness of 1 to 10 μm.

18. The protective film according to claim 16, which has an optical density of 1.0 or higher at a wavelength of 355 nm or 1,064 nm.
